(19) United States
(12) Patent Application Publication
(10) Pub. No.: US 2015/0004767 A1
(43) Pub. Date: Jan. 1, 2015

(54) METHOD OF FORMING NICKEL SALICIDE ON A SILICON-GERMANIUM LAYER

(71) Applicant: SHANGHAI HUALI MICROELECTRONICS CORPORATION, Shanghai (CN)

(72) Inventors: Junsheng Cai, Shanghai (CN); Xiangtao Kong, Shanghai (CN); Xiaogang Han, Shanghai (CN); ChienWei Chen, Shanghai (CN); HsuSheng Chang, Shanghai (CN)

(73) Assignee: SHANGHAI HUALI MICROELECTRONICS CORPORATION, Shanghai (CN)

(21) Appl. No.: 14/097,771

(22) Filed: Dec. 5, 2013

(30) Foreign Application Priority Data
Jun. 26, 2013 (CN) 201310258323.6

(51) Int. Cl. H01L 29/66; H01L 21/285

(52) U.S. Cl. CPC H01L 29/665; H01L 21/28518
USPC 438/285

(57) ABSTRACT

A method of forming nickel self-aligned silicide (Ni-salicide) is disclosed, the method including the following steps in the sequence set forth: providing a substrate; forming a gate on the substrate and forming a SiGe source and a SiGe drain beneath a surface of the substrate; growing a silicon epitaxial layer over the SiGe source and the SiGe drain; amorphizing the silicon epitaxial layer; depositing a Ni—Pt layer over the amorphized silicon epitaxial layer; performing a first rapid thermal anneal process to cause Ni—Pt alloy and the amorphized silicon epitaxial layer to react; removing the unreacted Ni—Pt alloy by wet etching; and performing a second rapid thermal anneal process to form a Ni-salicide.

### CROSS-REFERENCES TO RELATED APPLICATIONS

This application claims the priority of Chinese patent application number 201310258323.6, filed on Jun. 26, 2013, the entire contents of which are incorporated herein by reference.

### TECHNICAL FIELD

The present invention relates to semiconductor integrated circuits and the fabrication thereof. More particularly, the invention relates to methods of forming nickel self-aligned silicide (Ni-salicide) on a silicon-germanium (SiGe) layer.

### BACKGROUND

The Ni-salicide process is being employed as a key section in complementary metal oxide semiconductor (CMOS) fabrication as it can not only effectively reduce bias resistances of transistor source, drain and gate regions, but also decrease contact resistances thereof. In this art, a Ni-salicide layer of a low resistivity and homogeneous texture typically results from a low-temperature reaction between a Ni-platinum (Pt) alloy and an underlying silicon substrate.

In recent years, due to its high hole mobility and other characteristics, the SiGe material has found widespread use in providing source and drain regions of p-channel metal-oxide semiconductor field effect transistors (p-MOSFET's). FIG. 1a to FIG. 1c schematically show the progression of a conventional method of forming Ni-salicide on a SiGe layer, in which, FIG. 1a illustrates a semiconductor substrate having a SiGe layer (consisting of a SiGe source 101 and a SiGe drain 102) formed therein and a gate 103 formed thereon; FIG. 1b depicts FIG. 1a with a Ni—Pt layer 104 deposited over the SiGe layer and the gate 103; and FIG. 1c depicts FIG. 1b after the Ni-salicide 105 is formed by performing a first anneal to bring the SiGe source 101, the SiGe drain 102, the gate 103 and the Ni—Pt layer 104 into reaction, removing the unreacted Ni—Pt alloy by a wet etching process and performing a second anneal.

Despite the above described transistor performance enhancement effect, there are still some disadvantages accompanying the employment of the SiGe material. For example, compared to forming Ni-salicide with silicon and the Ni—Pt alloy which involves a first anneal performed at a temperature of 280° C. to 300° C. to allow for the reaction between the two materials and a second anneal performed at a temperature of 500° C. subsequent to removing the unreacted Ni—Pt alloy by a wet etching process, the formation of Ni-salicide on the SiGe layer requires the first anneal to be performed at a temperature of 300° C. to 350° C. and the second anneal at 500° C. That is, there is a temperature difference of 20° C. to 50° C. in terms of the first annual between the two schemes. Moreover, the nickel silicide (NiSi), formed by Ni—Pt and silicon, has a sheet resistivity of 12 ohm per square, 50% higher than the sheet resistivity of the nickel germano-silicide (NiSiGe) formed by Ni—Pt and the SiGe layer, which is 8 ohm per square. Furthermore, after the Ni-salicide layer formed from the SiGe layer and Ni—Pt alloy is annealed, agglomerates will be present therein and germanium will diffuse onto the surface thereof, which causes great decrease in the texture uniformity of the Ni-salicide layer and deterioration of electrical properties of the device being fabricated.

Conclusively, compared to the Ni-salicide formation on a silicon surface, forming Ni-salicide on the SiGe layer has several disadvantageous, including requiring a higher anneal temperature and resulting in a product with textural agglomerates, germanium's surface-bound diffusion and a reduced sheet resistivity, which affects the device performance enhancement benefiting from the employment of the SiGe layer.

### SUMMARY OF THE INVENTION

The present invention is directed to a method of forming Ni-salicide on a SiGe layer, which is capable of lowering anneal temperature and addressing the above described Ni-salicide texture non-uniformity issue caused by local agglomeration, surface-bound germanium diffusion and other post-annealing phenomena.

The present invention provides a method of forming Ni-salicide, including the following steps in the sequence set forth: providing a substrate; forming a gate on the substrate and forming a SiGe source and a SiGe drain beneath a surface of the substrate; growing a silicon epitaxial layer over the SiGe source and the SiGe drain; amorphizing the silicon epitaxial layer; depositing a Ni—Pt layer over the amorphized silicon epitaxial layer; performing a first rapid thermal anneal process to cause Ni—Pt alloy and the amorphized silicon epitaxial layer to react; removing the unreacted Ni—Pt alloy by wet etching; and performing a second rapid thermal anneal process to form a Ni-salicide.

In an embodiment, amorphizing the silicon epitaxial layer may be accomplished by selective ion implantation.

In an embodiment, silicon ions, germanium ions, or a mixture thereof, may be implanted in the selective ion implantation.

In an embodiment, the silicon epitaxial layer may have a thickness of 30 Å to 120 Å.

In an embodiment, the selective ion implantation may be performed at an energy of 5 KeV to 50 KeV and a dose of 1.0×10¹³/cm² to 1.0×10¹⁶/cm².

In an embodiment, the Ni—Pt layer may have a thickness of 80 Å to 120 Å.

In an embodiment, the first RTA may be performed at a temperature of 280° C. to 320° C.

In an embodiment, the second RTA may be performed at a temperature of 500° C.

One advantage of the present invention over the prior art is that Ni-salicide is formed on a silicon epitaxial layer deposited over a SiGe layer instead of directly on the SiGe layer. As such, the Ni-salicide formation can be accomplished at a lower annealing temperature, which can reduce the process cost and expand the process window. In addition, the Ni-salicide layer formed by the method of the invention has high texture uniformity without local agglomerates and germanium's surface-bound diffusion, thus contributing to the performance enhancement of the device being fabricated.

A second advantage is that Ni-salicide formed by the present invention has a lower resistance than that formed in the prior art, resulting in reduction of device power consumption.

A third advantage is that the silicon layer is amorphized to destroy the silicon's crystalline lattice structure before it reacts with the Ni—Pt alloy. This can prevent the formation of bark-like portions along the Ni-salicide layer and improve the texture uniformity thereof to prevent the occurrence of short circuits and increase the reliability of the associated device.

### BRIEF DESCRIPTION OF DRAWINGS

FIGS. 1a to 1c are schematics illustrating a prior art process for forming Ni-salicide.

FIG. 2 depicts a flowchart graphically illustrating a method of forming Ni-salicide on a SiGe layer in accordance with one embodiment of the present invention.

FIGS. 3a to 3e schematically illustrate a method of forming Ni-salicide on a SiGe layer in accordance with one embodiment of the present invention.

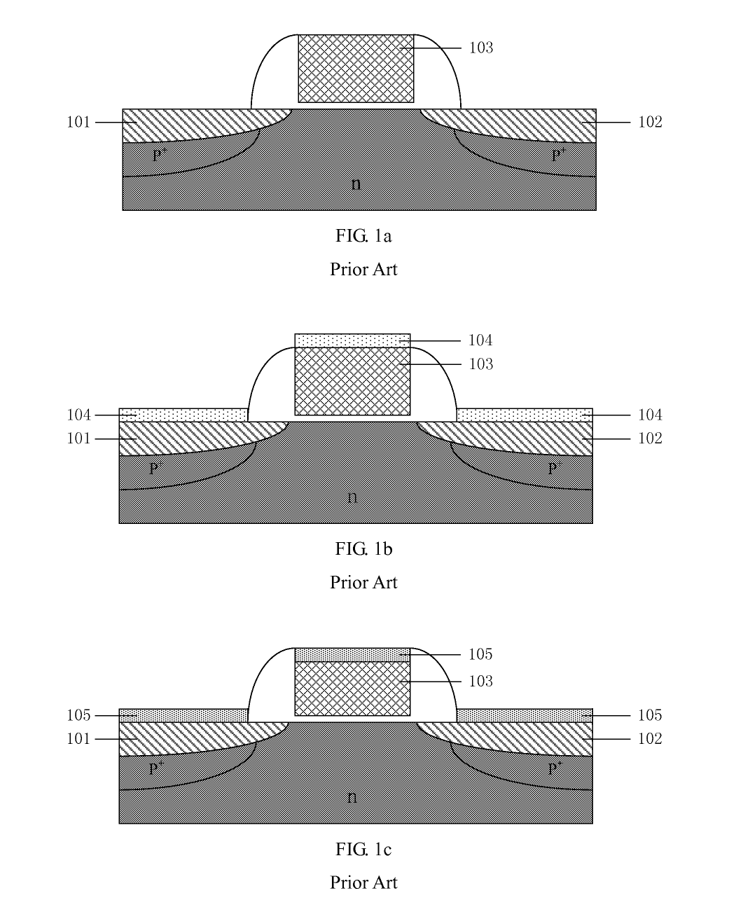

### DETAILED DESCRIPTION

The present invention will become better understood with reference to the following description, taken in conjunction with the accompanying drawings. It is a matter of course that the invention is not limited to the particular embodiments disclosed in the description, and all alternatives made by substituting elements thereof for equivalents known to those skilled in the art are construed to be within the scope of the invention.

The accompanying drawings illustrate the embodiments of the particular invention and serve to explain the principles of the invention in greater detail. For the sake of simplicity of explanation, the drawings are not necessarily drawn to scale, and this should not be considered as a limitation to the present invention.

The present invention is based on the principal of resulting in Ni-salicide from the reaction of a Ni—Pt alloy and a silicon epitaxial layer instead of with a SiGe layer (e.g., a SiGe source region and a SiGe drain region) to lower the temperature of an annealing process involved therein, prevent the occurrence of local agglomeration in texture, surface-bound germanium diffusion and other undesirable post-annealing phenomena, and increase the texture uniformity of the resulting Ni-salicide layer, so as to ensure for good electrical properties of the device being fabricated and decrease the power consumption thereof through resistance reduction.

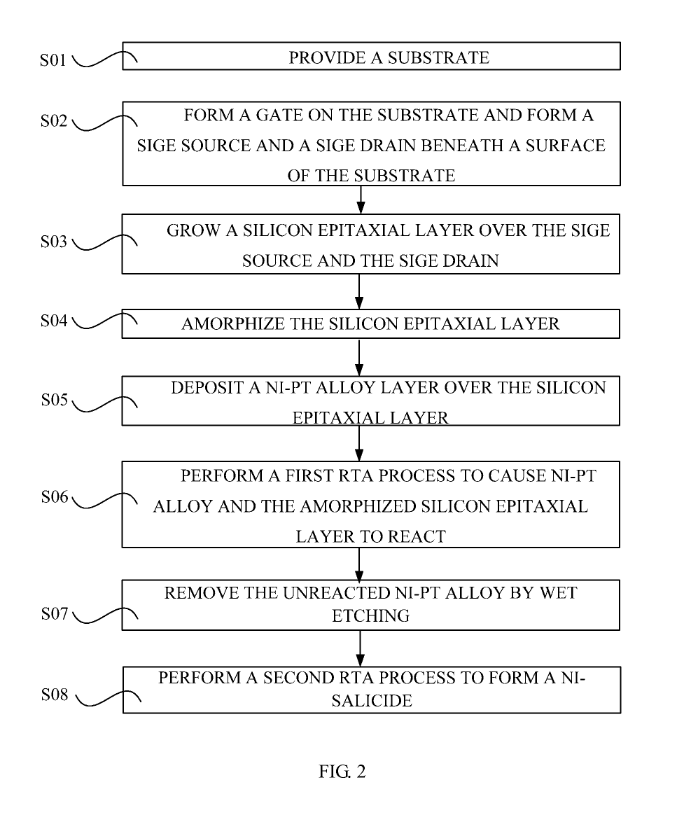

FIG. 2 depicts a flowchart graphically illustrating a method of forming Ni-salicide on a SiGe layer in accordance with one embodiment of the present invention. As illustrated, the method includes the following steps of:

S01: providing a substrate;

S02: forming a gate on the substrate and forming a SiGe source and a SiGe drain beneath a surface of the substrate;

S03: growing a silicon epitaxial layer over the SiGe source and SiGe drain;

S04: amorphizing the silicon epitaxial layer;

S05: depositing a Ni—Pt layer over the amorphized silicon epitaxial layer;

S06: performing a first rapid thermal anneal (RTA) process to cause Ni—Pt alloy and the amorphized silicon epitaxial layer to react;

S07: removing the unreacted Ni—Pt alloy by wet etching; and

S08: performing a second RTA process to form a Ni-salicide.

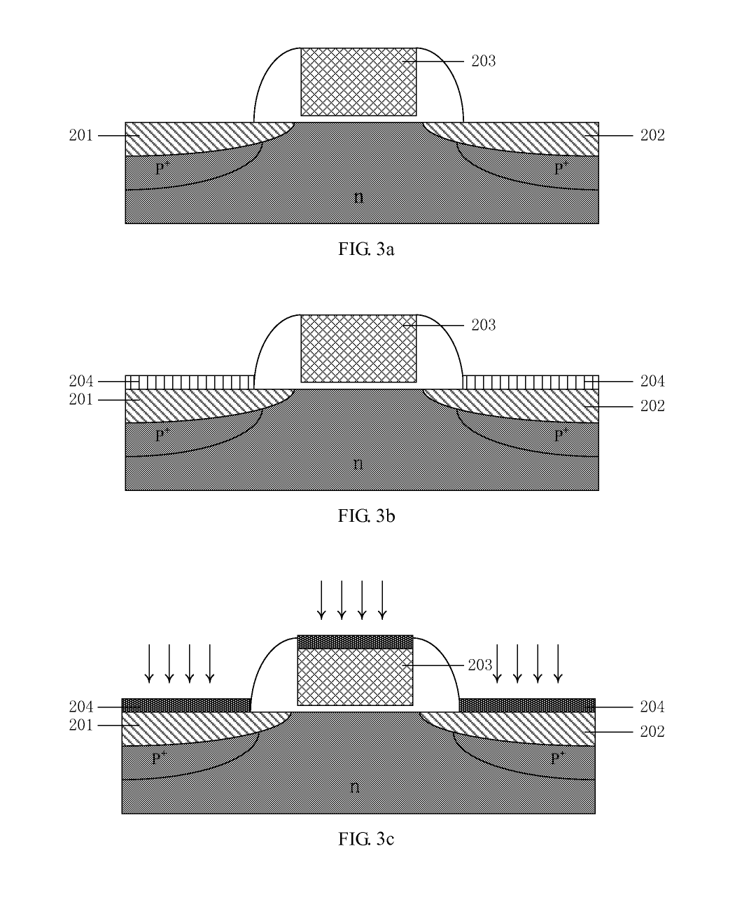

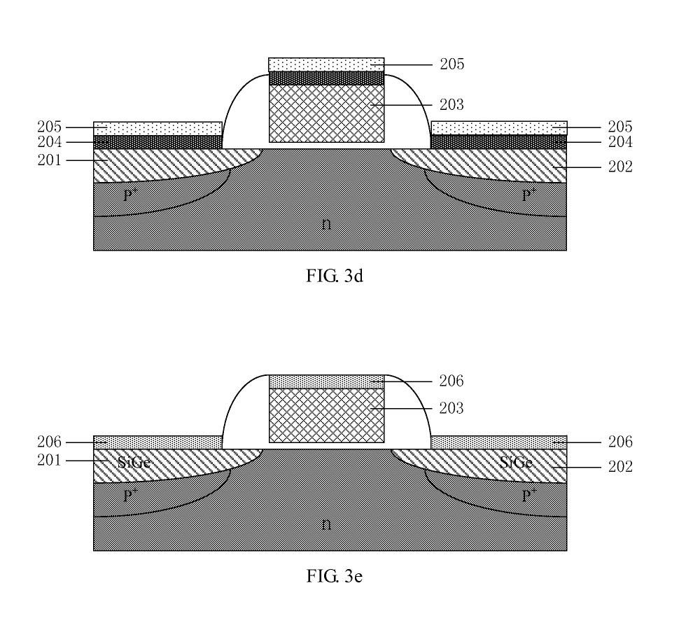

The present invention is described in greater detail below, by referencing FIG. 2, taken in conjunction with FIGS. 3a to 3e, which are schematics illustrating the method of FIG. 2.

In S01 and S02, referring to FIG. 3a, a gate 203 is formed on, and a SiGe source 201 and a SiGe drain 202 are formed beneath a surface of, a substrate in a conventional manner. The gate 203 may be formed from polysilicon.

In S03, referring to FIG. 3b, a silicon epitaxial layer 204 is formed over the SiGe source 201 and the SiGe drain 202 to a thickness of 30 Å to 120 Å such as, for example, 30 Å, 50 Å, 70 Å, 90 Å, 100 Å or 120 Å, with 100 Å being preferred.

In S04, the silicon epitaxial layer 204 is amorphized by selective ion implantation where silicon ions, germanium ions, or a mixture thereof are implanted. In this step, a surface of the gate 203 may be amorphized concurrently, as shown in FIG. 3c. The amorphization step may serve to destroy the crystalline lattice structure of the silicon epitaxial layer 204 to prevent the subsequently formed Ni-salicide from growing in a particular direction along the orientation of silicon's periodic lattices. In this embodiment, the ion implantation may be performed at an energy of 5 KeV to 50 KeV such as, for example, 10 KeV, 20 KeV, 30 KeV, 40 KeV, or 50 KeV, with 25 KeV being preferred, and at a dose of 1.0×10¹³/cm² to 1.0×10¹⁶/cm² such as, for example, 1.0×10¹³/cm², 1.0×10¹⁴/cm², 1.0×10¹⁵/cm², or 1.0×10¹⁶/cm², with 1.0×10¹⁵/cm² being preferred.

In S05, a Ni—Pt layer 205 is deposited covering both the silicon epitaxial layer 204 and the gate 203 to form the structure as shown in FIG. 3d. Thickness of the Ni—Pt layer 205 may be so arranged, when considered in conjunction with the thickness of the silicon epitaxial layer 204, that the two layers are completely consumed in the reaction between themselves enabled in the subsequent step to avoid any impact on the underlying SiGe source 201 and SiGe drain 202. In this embodiment, the thickness of the Ni—Pt layer 205 may range from 80 Å to 120 Å such as, for example, 80 Å, 90 Å, 100 Å, 110 Å, or 120 Å, with 90 Å being preferred.

In S06, a first thermal rapid anneal (RTA) process is performed to cause the Ni—Pt layer 205 to react with the amorphized silicon epitaxial layer 204 and the amorphized gate 203. The first RTA process may be performed at a temperature of 280° C. to 320° C.

In S07, the unreacted Ni—Pt alloy is removed by wet etching. In S08, referring to FIG. 3e, a second RTA process is performed to finalize the formation of the Ni-salicide 206. The second RTA process may be performed at a temperature of 500° C.

In the method of the present invention, as noted above, it is preferred that the silicon epitaxial layer 204 and the Ni—Pt layer 205 are totally consumed in their reaction such that there will be no impact on the SiGe source 201 and SiGe drain 202. This is achievable by properly setting a set of process parameters, including thicknesses of the silicon epitaxial layer 204 and Ni—Pt layer 205, implantation energy and implantation dose of the amorphization step. Accordingly, in other embodiments, the method may be employed with the set of process parameters having different values. In one of these embodiments, the silicon epitaxial layer has a thickness of 100 Å, the Ni—Pt layer has a thickness of 90 Å, and the amorphizing ion implantation is performed at an energy of 5 KeV to 50 KeV and a dose of 1.0×10¹³/cm² to 1.0×10^{16/cm}². In another one of these embodiments, the silicon epitaxial layer has a thickness of 60 Å, the Ni—Pt layer has a thickness of 80 Å, and the ion implantation is performed at an energy of 5 KeV to 50 KeV and a dose of 1.0×10¹⁴/cm² to 1.0×10¹⁶/cm².

In conclusion, through forming Ni-salicide from the reaction between a Ni—Pt alloy and a silicon epitaxial layer instead of a SiGe layer, the method of the present invention is capable of lowering the annealing temperature, reducing the process cost and expanding the process window, preventing the occurrence of local agglomeration, surface-bound germanium diffusion and other undesirable post-annealing phenomena and increasing the texture uniformity of the resulting Ni-salicide layer, thereby ensuring for good electrical properties of the device being fabricated. Other advantages of the present invention over the prior art include: 1) Ni-salicide resulting from the reaction of the silicon epitaxial layer and Ni—Pt alloy has a lower resistance, thus reducing device power consumption; and 2) amorphizing the silicon epitaxial layer can destroy the silicon's crystalline lattice structure and hence improve the texture uniformity of the resulting Ni-salicide layer and prevent the formation of bark-like portions along the layer, thereby preventing the occurrence of short circuits and increasing the reliability of the device being fabricated.

The foregoing description is intended merely to illustrate specific embodiments of the present invention and not to limit the scope of the invention. Alterations and modifications made by those having ordinary skill in the art in light of the above teachings are considered to be within the scope of the invention as defined in the following claims.

What is claimed is:

1. A method of forming nickel self-aligned silicide (Ni-salicide), comprising the following steps in the sequence set forth:
providing a substrate;
forming a gate on the substrate and forming a SiGe source and a SiGe drain beneath a surface of the substrate;
growing a silicon epitaxial layer over the SiGe source and the SiGe drain;
amorphizing the silicon epitaxial layer;
depositing a Ni—Pt layer over the amorphized silicon epitaxial layer;
performing a first rapid thermal anneal process to cause Ni—Pt alloy and the amorphized silicon epitaxial layer to react;
removing the unreacted Ni—Pt alloy by wet etching; and
performing a second rapid thermal anneal process to form a Ni-salicide.

2. The method of claim 1, wherein amorphizing the silicon epitaxial layer is accomplished by selective ion implantation.

3. The method of claim 2, wherein silicon ions, germanium ions, or a mixture thereof, are implanted in the selective ion implantation.

4. The method of claim 3, wherein the silicon epitaxial layer has a thickness of 30 Å to 120 Å.

5. The method of claim 4, wherein the selective ion implantation is performed at an energy of 5 KeV to 50 KeV and a dose of 1.0×10¹³/cm² to 1.0×10¹⁶/cm².

6. The method of claim 1, wherein the Ni—Pt layer has a thickness of 80 Å to 120 Å.

7. The method of claim 1, wherein the first rapid thermal anneal process is performed at a temperature of 280° C. to 320° C.

8. The method of claim 1, wherein the second rapid thermal anneal process is performed at a temperature of 500° C.
